(19) United States
(12) Patent Application Publication
(10) Pub. No.: US 2011/0292960 A1
(43) Pub. Date: Dec. 1, 2011

(54) WAVELENGTH TUNABLE SEMICONDUCTOR LASER

(75) Inventors: Hajime Shoji, Kanagawa (JP); Takuya Fujii, Kanagawa (JP); Tsutomu Ishikawa, Kanagawa (JP)

(73) Assignees: SUMITOMO ELECTRIC DEVICE INNOVATIONS, INC., Yokohama-shi (JP); SUMITOMO ELECTRIC INDUSTRIES, LTD., Osaka (JP)

(21) Appl. No.: 13/117,541

(22) Filed: May 27, 2011

(30) Foreign Application Priority Data
May 27, 2010 (JP) 2010-122140

(51) Int. Cl. H01S 5/026

(52) U.S. Cl. 372/50.11

(57) ABSTRACT

A wavelength tunable semiconductor laser includes: a first facet having reflectivity of 10% or more; a second facet; a wavelength selection portion between the first facet and the second facet; and an optical absorption region between the first facet and the wavelength selection portion. Another wavelength tunable semiconductor laser includes: a first facet having reflectivity of 10% or more to inside of the semiconductor laser; a second facet for output; a wavelength selection portion having diffraction gratings and positioned between the first and the second facet; an optical absorption region located between the first facet and the wavelength selection portion.

### CROSS-REFERENCE TO RELATED APPLICATION

This application is based upon and claims the benefit of priority of the prior Japanese Patent Application No. 2010-122140, filed on May 27, 2010, the entire contents of which are incorporated herein by reference.

### BACKGROUND

(i) Technical Field

The present invention relates to a wavelength tunable semiconductor laser.

(ii) Related Art

A wavelength tunable semiconductor laser selecting variable oscillation wavelength is being developed as a WDM (Wavelength Division Multiplexing) communication is spread. The wavelength tunable semiconductor laser has a wavelength selection portion therein. Japanese Patent Application Publication No. 2007-048988 discloses that an AR (Anti Reflection) layer is formed on both facets of the wavelength tunable semiconductor laser. This restrains reflection at the facets.

### SUMMARY

There is a case where an output light from a semiconductor laser acts as a stray light in a package housing a semiconductor laser. On the other hand, the AR layer is transparent with respect to an incoming light from outside. It is therefore necessary to restrain incoming of a stray light into both facets of a wavelength tunable semiconductor laser.

In particular, the wavelength tunable semiconductor laser is essentially capable of selecting variable oscillation wavelengths. Therefore, the wavelength tunable semiconductor laser may oscillate at an undesirable wavelength when a stray light is fed into the wavelength tunable semiconductor laser. It is therefore important to take measures against the stray light.

In order to take measures against the stray light, it is necessary to restrain incoming of the stray light into the wavelength tunable semiconductor laser or another optical element by considering component layout in a package.

However, it is not possible to secure a sufficient space in a downsized package. It is therefore difficult to take measures against the stray light. High assembly accuracy is needed and thereby cost may be increased, even if the component layout taking measures against the stray light is established.

It is an object of the present invention to provide a wavelength tunable semiconductor laser taking measures against a stray light.

According to an aspect of the present invention, there is provided a wavelength tunable semiconductor laser including: a first facet having reflectivity of 10% or more; a second facet; a wavelength selection portion between the first facet and the second facet; and an optical absorption region between the first facet and the wavelength selection portion. With the structure, the wavelength tunable semiconductor laser gets high resistivity against a stray light.

The optical absorption region may be between a p-type semiconductor layer an n-type semiconductor layer; and a conductor may electrically couple the p-type semiconductor layer and the n-type semiconductor layer. The wavelength selection portion may have one of structures, the structures being a combination of a SG-DFB and a CSG-DBR, a combination of two SG-DFBs, or a combination of two SG-DBRs and a phase shift region between the two SG-DBRs, the SG-DFB having a plurality of segments including a space region between diffraction gratings and having a gain, the CSG-DBR having a plurality of segments including a space region between diffraction gratings, each space region having a different length, the SG-DBR having a plurality of segments including a space region between diffraction gratings.

Output optical intensity from the first facet may be 1/100 or less of output optical intensity from the second facet. The reflectivity of the first facet may be 20% or more. A dielectric multi-layer film may be formed on the first facet, the dielectric multi-layer film having one or more combination of a first dielectric material having a thickness corresponding to an optical length of ¼ of an oscillation wavelength of the wavelength tunable semiconductor laser and a second dielectric material having a thickness corresponding to the optical length of ¼ of the oscillation wavelength of the wavelength tunable semiconductor laser and having refractive index less than that of the first dielectric material.

The first facet may be a cleavage face. A resin may be adhered to the cleavage face. A dielectric material having a thickness corresponding to an optical length of 1/10 or less of an oscillation wavelength of the wavelength tunable semiconductor laser may be adhered to the cleavage face. The optical absorption region may be made of a material having absorption edge wavelength longer than an oscillation wavelength of the wavelength tunable semiconductor laser. The optical absorption region may be made of the same material as an active layer for giving a gain to the wavelength tunable semiconductor laser. The reflectivity of the second facet may be 1.0% or less.

According to another aspect of the present invention, there is provided a wavelength tunable semiconductor laser including: a first facet having reflectivity of 10% or more to inside of the semiconductor laser; a second facet for output; a wavelength selection portion having diffraction gratings and positioned between the first and the second facet; an optical absorption region located between the first facet and the wavelength selection portion.

The wavelength selection portion may have a SG-DFB section and a CSG-DBR section; the SG-DFB section may have a plurality of segments with a gain, the segments having a space region located between diffraction gratings; and the CSG-DBR section may have a plurality of segments, the segments having a space region located between diffraction gratings, at least two segments having the space region of different length.

The SG-DFB section may have active regions and refractive index-controllable regions; and the active regions and refractive index-controllable regions may be positioned alternately. Output optical intensity from the first facet may be 1/100 or less of output optical intensity from the second facet. Refractivity of the first facet to inside of the semiconductor laser may be 20% or more. Refractivity of the second facet to inside of the semiconductor laser may be 10% or less.

### BRIEF DESCRIPTION OF THE DRAWINGS

FIG. 1 illustrates a schematic cross sectional view of a semiconductor laser in accordance with a first embodiment;

FIG. 2 illustrates a semiconductor laser in a case where a rear facet is a cleavage face;

FIG. 3 illustrates a wiring introducing electrical power generated through optical absorption in an optical absorption region to outside;

FIG. 4A to FIG. 4C illustrate a structure example of an optical absorption layer;

FIG. 5 illustrates a schematic cross sectional view of a semiconductor laser in accordance with a second embodiment;

FIG. 6 illustrates a schematic cross sectional view of a semiconductor laser in accordance with a third embodiment;

FIG. 7 illustrates a schematic cross sectional view of a semiconductor laser in accordance with a fourth embodiment; and

FIG. 8 illustrates a schematic cross sectional view of a semiconductor laser in accordance with a fifth embodiment.

### DETAILED DESCRIPTION

A description will be given of a best mode for carrying the present invention.

### First Embodiment

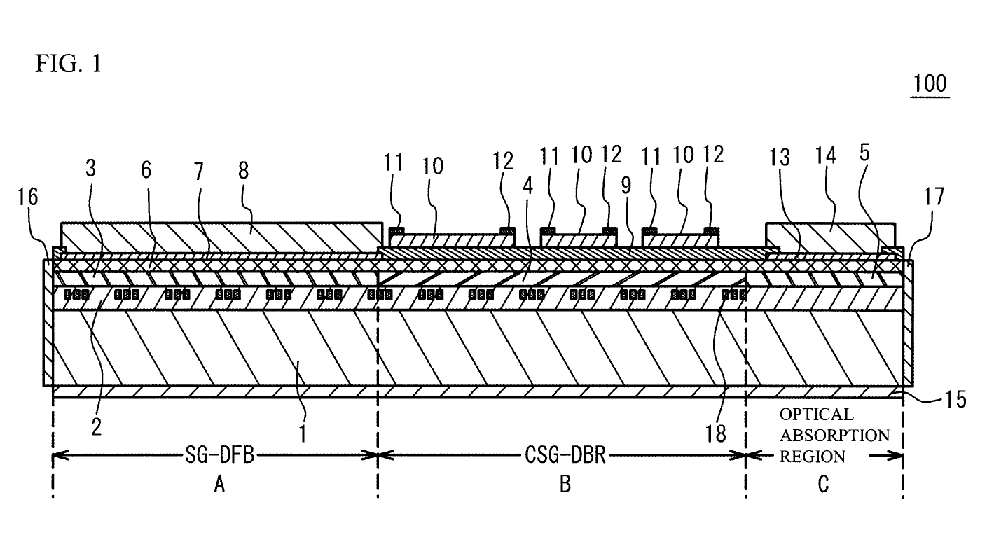

FIG. 1 illustrates a schematic cross sectional view of a semiconductor laser 100 in accordance with a first embodiment. As illustrated in FIG. 1, the semiconductor laser 100 has a structure in which a SG-DFB (Sampled Grating Distributed Feedback) region A, a CSG-DBR (Chirped Sampled Grating Distributed Reflector) region B, and an optical absorption region C are combined in this order. In the semiconductor laser 100, the SG-DFB region A and the CSG-DBR region B act as a wavelength selection portion.

The SG-DFB region A has a structure in which a lower cladding layer 2, an active layer 3, an upper cladding layer 6, a contact layer 7 and an electrode 8 are laminated on a substrate 1. The CSG-DBR region B has a structure in which the lower cladding layer 2, an optical waveguide layer 4, the upper cladding layer 6, an insulating layer 9 and heaters 10 are laminated on the substrate 1. Each of the heaters 10 has a power supply electrode 11 and a ground electrode 12. The optical absorption region C has a structure in which the lower cladding layer 2, an optical absorption layer 5, the upper cladding layer 6, a contact layer 13 and an electrode 14 are laminated on the substrate 1.

The substrate 1, the lower cladding layer 2 and the upper cladding layer 6 are integrally formed in the SG-DFB region A, the CSG-DBR region B and the optical absorption region C. The active layer 3, the optical waveguide layer 4, and the optical absorption layer 5 are formed on the same plane. An AR (Anti Reflection) layer 16 is formed on an facet of the substrate 1, the lower cladding layer 2, the active layer 3 and the upper cladding layer 6 on the side of the SG-DFB region A. The AR layer 16 acts as a front facet of the semiconductor laser 100. A reflection layer 17 is formed on an facet of the substrate 1, the lower cladding layer 2, the optical absorption layer 5, and the upper cladding layer 6 on the side of the optical absorption region C. The reflection layer 17 acts as a rear facet of the semiconductor laser 100.

A plurality of diffraction gratings (corrugations) 18 are formed in the lower cladding layer 2 of the SG-DFB region A and the CSG-DBR region B in a given interval. The SG-DFB region A and the CSG-DBR region B have a plurality of segments. The segment is a region in which one region having the diffraction grating 18 and one space portion not having the diffraction grating 18 are combined. The diffraction grating 18 is made of a material having a refractive index that is different from that of the lower cladding layer 2. The material of the diffraction grating 18 is, for example, made of Ga_{0.22}In_{0.78}As_{0.47}P_{0.53} when the lower cladding layer 2 is made of InP.

The diffraction grating 18 may be formed with a patterning with use of a dual beam interference exposure method. The space region between two diffraction gratings 18 may be formed by exposing a resist with a pattern of the diffraction grating 18 and exposing an area of the resist corresponding to the space region after that.

In the CSG-DBR region B, at least two of the segments have a different optical length. Thus, peak intensity of wavelength characteristics of the CSG-DBR region B depends on wavelength. On the other hand, each optical length of the segments of the SG-DFB region A is substantially equal to each other. The combination of the SG-DFB region A and the CSG-DBR region B allows a stable laser oscillation at a desirable wavelength with use of vernier effect.

The substrate 1 is, for example, a crystal substrate made of n-type InP. The lower cladding layer 2 has n-type conductivity. The upper cladding layer 6 has p-type conductivity. The lower cladding layer 2 and the upper cladding layer 6 are, for example, made of InP. The lower cladding layer 2 and the upper cladding layer 6 confines a light in the active layer 3, the optical waveguide layer 4 and the optical absorption layer 5.

The active layer 3 is made of semiconductor having a gain. The active layer 3 may have quantum well structure in which a well layer made of Ga_{0.32}In_{0.38}As₀₉₂P_{0.08} having a thickness of 5 nm and a barrier layer made of Ga_{0.22}In_{0.78}As_{0.47}P_{0.53} having a thickness of 10 nm are laminated alternately.

The optical waveguide layer 4 is, for example, made of bulk semiconductor layer, and may be made of Ga_{0.22}In_{0.78}As_{0.47}P_{0.53}.

The optical absorption layer 5 may be made of a material absorbing a light with respect to an oscillation wavelength of the wavelength tunable semiconductor laser 100. The optical absorption layer 5 is made of a material having an absorption edge wavelength at longer wavelength side relative to the laser oscillation wavelength of the wavelength tunable semiconductor laser 100. It is preferable that the absorption edge wavelength is longer than the longest oscillation wavelength of the oscillation wavelengths of the wavelength tunable semiconductor laser 100.

The optical absorption layer 5 may have quantum well structure in which a well layer made of Ga_{0.47}In_{0.53}As having a thickness of 5 nm and a barrier layer made of Ga_{0.28}In_{0.72}As_{0.61}P_{0.39} having a thickness of 10 nm are laminated alternately. The optical absorption layer 5, is for example, made of a bulk semiconductor, and may be made of Ga_{0.46}In_{0.54}As_{0.98}P_{0.02}. The optical absorption layer 5 may be made of the same material as the active layer 3. In this case, the active layer 3 and the optical absorption layer 5 may be formed with a single process. Therefore, the manufacturing process may be simplified.

The contact layers 7 and 13 are, for example, made of p-type Ga_{0.47}In_{0.53}As crystal. The insulating layer 9 is a protective layer made of an insulator such as SiN or SiO₂. The heater 10 is a thin film resistor such as NiCr. Each heater 10 may extend through a plurality of the segments in the CSG-DBR region B.

The electrodes 8 and 14, the power supply electrode 11 and the ground electrode 12 are made of conductive material such as Au (gold). A reverse face electrode 15 is formed on a lower face of the substrate 1. The reverse face electrode 15 extends through the SG-DFB region A, the CSG-DBR region B and the optical absorption region C.

The AR layer 16 is an facet layer having reflectivity of 1.0% or less, and thereby makes the facet substantially anti-reflection. It is preferable that the AR layer 16 has reflectivity of 0.3% or less. The AR layer 16 may be a dielectric layer made of MgF₂, TiON or the like.

On the other hand, the reflection layer 17 has reflectivity larger than that of the AR layer 16. For example, the reflectivity of the reflection layer 17 is 10% or more. The reflectivity means reflectivity with respect to an inner portion of a semiconductor laser.

The reflection layer 17 has one or more combination of a high refractive index dielectric material and a low refractive index dielectric material. The high refractive index dielectric material and the low refractive index dielectric material have a thickness of an optical length of ¼ of an oscillation wavelength. It is preferable that the above-mentioned oscillation wavelength is around a center of a wavelength tunable range of the wavelength tunable semiconductor laser. For example, a multi-layer film in which SiO₂ of 260 nm and TiON of 150 nm are laminated alternately three times may be used. In this case, the reflectivity is approximately 90% in an oscillation wavelength range of 1.5 μm. Two-layer film in which SiO₂ of 260 nm and Si of 120 nm are laminated may be used. In this case, the reflectivity is approximately 80% in the oscillation wavelength range of 1.5 μm.

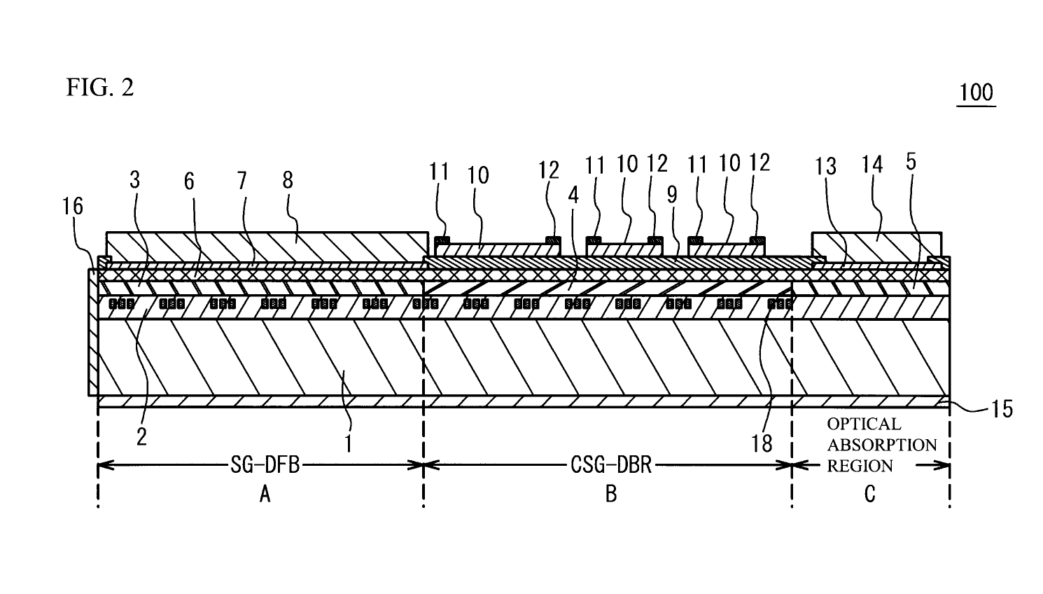

As illustrated in FIG. 2, a rear facet of the semiconductor laser 100 may be a cleavage face, and the reflection layer 17 may not be provided. In this case, the rear facet of the semiconductor laser 100 has reflectivity of approximately 30% in the oscillation wavelength range of 1.5 μm. When the rear facet of the semiconductor laser 100 is cleavage face, a process for forming the reflection layer 17 is not needed and the cost may be reduced. And, reduction of yield ratio caused by manufacturing tolerance of the reflection layer 17 may be restrained.

A potted resin may be adhered to the cleavage face of the semiconductor laser 100 acting as the rear facet. In this case, the rear facet of the semiconductor laser 100 has reflectivity of approximately 10% in the oscillation wavelength range of 1.5 μm. Silicone-based resin may be used as the potted resin.

An edge-protective layer having a thickness of an optical length of 1/10 of the oscillation wavelength may be formed on the cleavage face of the rear facet. For example, the optical length of 1/10 of the oscillation wavelength is approximately 100 nm when silicon oxide is used as the edge-protective layer, in a case of a semiconductor laser oscillating in the 1.5 μm range. In this case, the reflectivity is 10% or more. It is more preferable that the thickness of the edge-protective face is 1/20 or less of the oscillation wavelength of the semiconductor laser. For example, the optical length of 1/20 of the oscillation wavelength is approximately 50 nm when silicon oxide is used as the edge-protective layer, in a case of a semiconductor laser oscillating in the 1.5 μm range. In this case, the reflectivity is 20% or more.

Next, a description will be given of an operation of the semiconductor laser 100. When a predetermined driving current is provided to the electrode 8, each heater 10 generates heat at a predetermined temperature. A TEC (Thermoelectric cooler) controls the temperature of the semiconductor laser 100 to be a predetermined temperature. Thus, the SG-DFB region A and the CSG-DBR region B select a wavelength, and the semiconductor laser 100 oscillates at the wavelength. The laser light is output from a front facet (on the side of the SG-DFB region A) to outside.

On the other hand, the laser light fed into the optical absorption layer 5 is absorbed in the optical absorption layer 5. A light reaching the rear facet is reflected to the optical absorption layer 5 again and is absorbed in the optical absorption layer 5 because the reflectivity of the rear facet of the semiconductor laser 100 is 10% or more. Therefore, optical outputting from the rear facet is substantially zero or extremely small.

Thus, generating of a stray light caused by the laser light from the rear facet is restrained in the semiconductor laser 100. It is preferable that the outputting of the rear facet is 1/100 of that of the front facet.

Incoming of a stray light to the rear facet from outside is restrained because the reflectivity of the rear facet of the semiconductor laser 100 is 10% or more. It is preferable that the reflectivity of the rear facet is 20% or more. And, the stray light fed into the semiconductor laser 100 through the rear facet is absorbed in the optical absorption layer 5. Therefore, intrusion of stray light into a resonator portion of the semiconductor laser 100 is restrained. In the semiconductor laser 100, the SG-DFB region A and the CSG-DBR region B act as the resonator portion.

In accordance with the embodiment, the generating of the stray light caused by the laser light output from the rear facet is restrained, because the optical absorption region and the rear facet having the reflectivity of 10% or more are provided. And, high resistivity with respect to the stray light fed into the rear facet is obtained. This allows reduction of layout limitation in the package housing the semiconductor laser 100. High assembly accuracy of the package is not needed. It is therefore not necessary to enlarge the package in order to take measures against the stray light. Therefore, the cost of the semiconductor laser device may be reduced, and counterpart against the stray light is established.

The laser light absorbed in the optical absorption layer 5 generates an electron-hole pair (a photo carrier). When the photo carrier is left in the optical absorption layer 5, optical absorbance of the optical absorption layer 5 may be reduced. It is therefore necessary to remove the photo carrier.

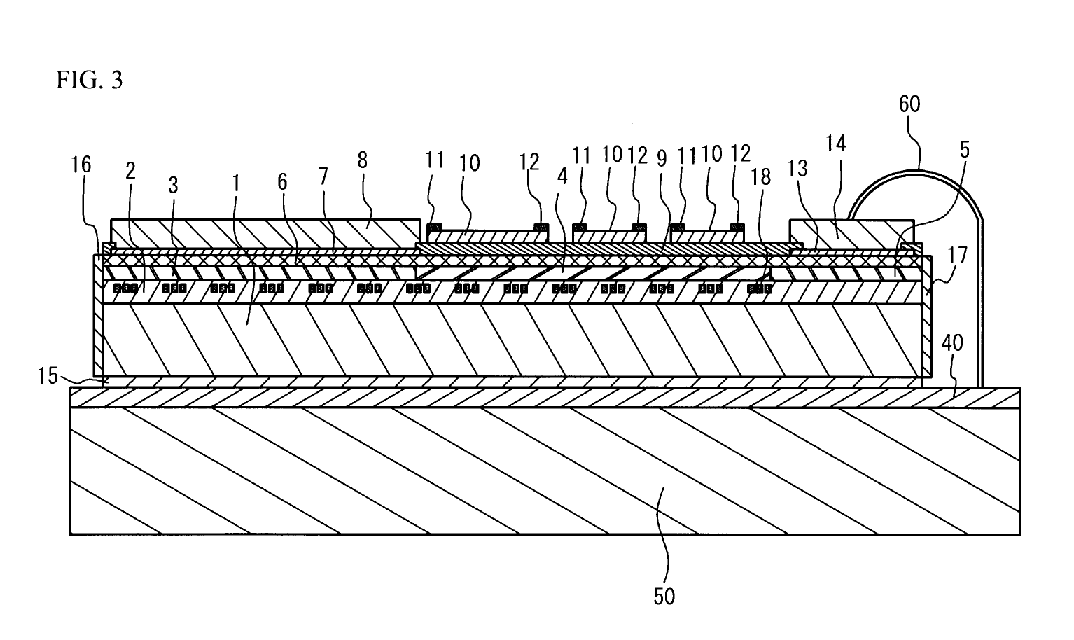

FIG. 3 illustrates a structure for introducing photo carrier generated by the optical absorption to outside. In an example of FIG. 3, a bonding wire 60 couples the electrode 14 and a metal pattern 40 on a mount carrier 50 in common. The metal pattern 40 is coupled to the reverse face electrode 15 of the semiconductor laser 100. Therefore, a potential of the n-type semiconductor (the lower cladding layer 2) is electrically coupled to that of the p-type semiconductor (the upper cladding layer 6) in common through the bonding wire 60 outside of the semiconductor laser 100. Thus, the photo carrier is introduced to outside of the semiconductor laser 100.

The substrate 1 is coupled to the ground potential via the metal pattern 40. The electrode 14 may introduce the photo carrier to outside when the electrode 14 is coupled to a ground electrode located in a package housing the semiconductor laser 100. If the substrate 1 of the semiconductor laser 100 is coupled to the ground potential, the photo carrier is introduced to outside when the ground electrode 12 and the electrode 14 of the heater 10 are coupled to each other. In this case, the ground electrode 12 and the electrode 14 may be coupled to each other with a bonding wire or a wiring pattern.

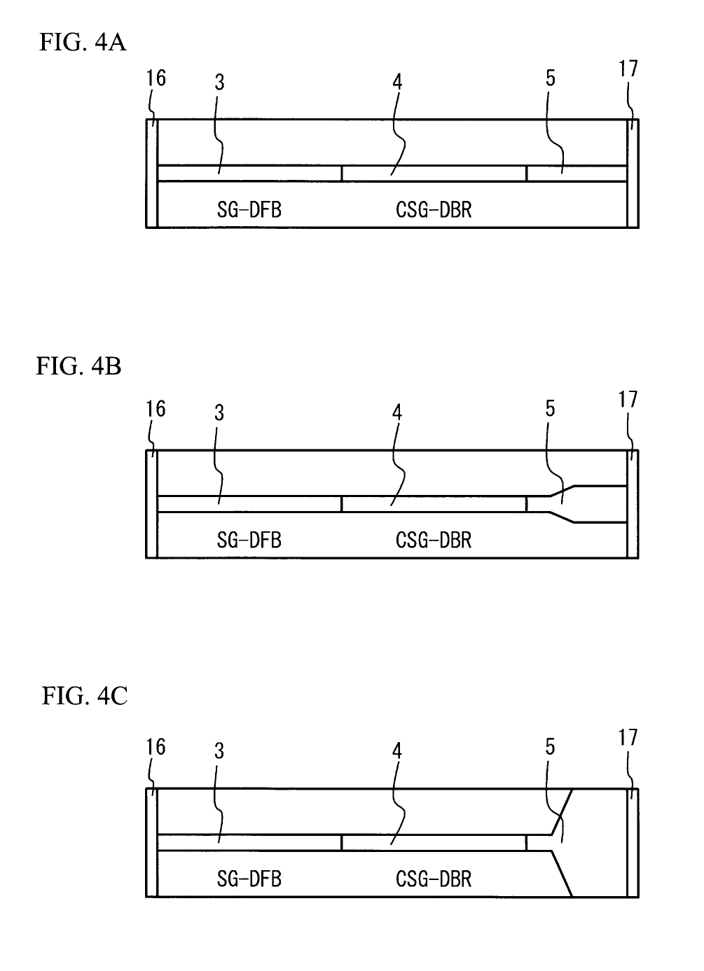

FIG. 4A to FIG. 4C illustrate an example of the optical absorption layer 5 in the optical absorption region C. FIG. 4A to FIG. 4C illustrate a plane view of the optical absorption layer 5.

As illustrated in FIG. 4A, the optical absorption layer 5 may have the same width as the active layer 3 and the optical waveguide layer 4. As illustrated in FIG. 4B, the width of the optical absorption layer 5 increases gradually from the optical waveguide layer 4 side toward the facet side. In this case, optical absorption amount of the optical absorption layer 5 gets larger on the side of the rear facet. Therefore, light intrusion through the rear facet is effectively restrained. As illustrated in FIG. 4C, the width of the optical absorption layer 5 may be enlarged to full width of the semiconductor laser 100. In this case, the optical absorption amount in the optical absorption layer 5 is further enlarged.

### Second Embodiment

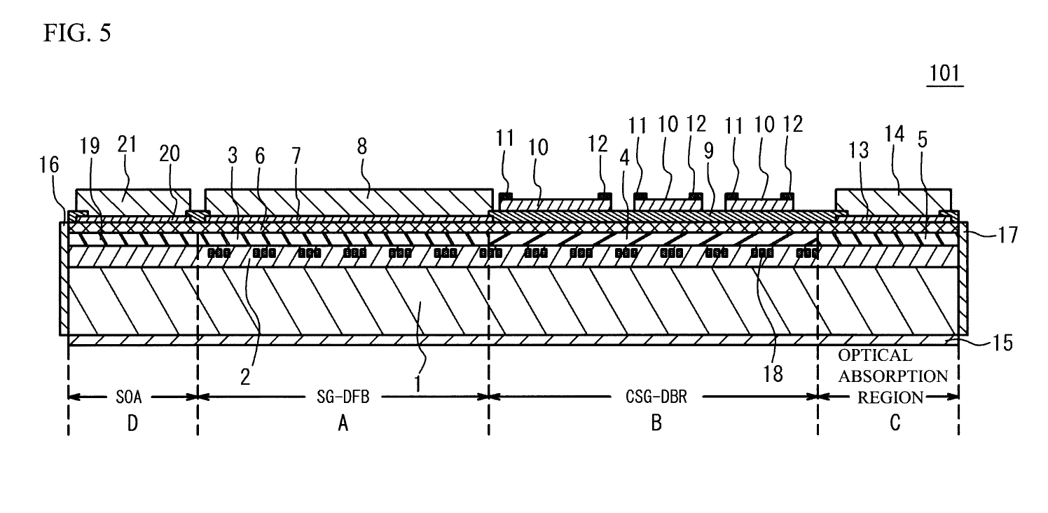

FIG. 5 illustrates a schematic cross sectional view of a semiconductor laser 101 in accordance with a second embodiment. As illustrated in FIG. 5, the semiconductor laser 101 has a structure in which a SOA (Semiconductor Optical Amplifier) region D is added to the semiconductor laser 100 of FIG. 1. The part except for the SOA region D is the same as the semiconductor laser 100 in accordance with the first embodiment. The SOA region D acts as an optical amplifier for amplifying a laser light.

The SOA region D is combined to the SG-DFB region A. The SOA region D has a structure in which the n-type lower cladding layer 2, an optical amplifying layer 19, the p-type upper cladding layer 6, a p-type contact layer 20, and an electrode 21 are laminated in this order on the substrate 1. The insulating layer 9 is further provided between the electrode 8 and the electrode 21.

The optical amplifying layer 19 has a gain and amplifies a light, when electrical current is provided to the optical amplifying layer 19 from the electrode 21. The optical amplifying layer 19 has quantum well structure, and has a structure in which a well layer made of Ga_{0.35}In_{0.65}As_{0.99}P_{0.01} having a thickness of 5 nm and a barrier layer made of Ga_{0.15}In_{0.85}As_{0.32}P_{0.68} having a thickness of 10 nm are laminated alternately. A bulk semiconductor made of Ga_{0.44}In_{0.56}As_{0.95}P_{0.05} may be used as the optical amplifying layer 19. The contact layer 20 is, for example, made of p-type Ga_{0.47}In_{0.53}As crystal. The optical amplifying layer 19 and the active layer 3 may be made of the same material. In this case, the optical amplifying layer 19 and the active layer 3 may be formed in a single process. Therefore, the manufacturing process may be simplified.

In the embodiment, the AR layer 16 is provided on an facet of the SOA region D that is a front facet of the semiconductor laser 101. The facet of the optical absorption region C acting as a rear facet has reflectivity of 10% or more as well as the first embodiment. The reflectivity is obtained when the multi-layer reflection film is formed, the cleavage face is used, potted resin is used, or adhered protective film is used, as well as the first embodiment.

The electrode 14 may be coupled to the potential of the substrate 1 in common in the semiconductor laser 101, as well as the first embodiment. This allows removal of the photo carrier.

Optical output of the semiconductor laser 101 is larger than that of the semiconductor laser 100 of the first embodiment, because the SOA region D is further provided. And, the semiconductor laser 101 has high resistivity against the stray light, because the optical absorption region C is provided and the rear facet has the reflectivity of 10% or more.

### Third Embodiment

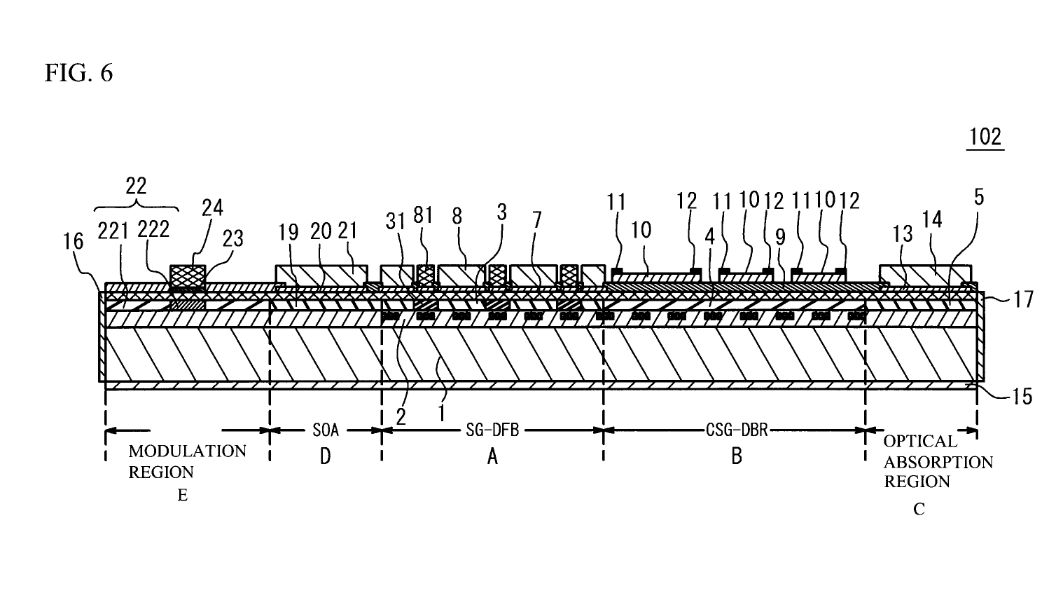

FIG. 6 illustrates a schematic cross sectional view of a semiconductor laser 102 in accordance with a third embodiment. The semiconductor laser 102 further has an optical modulation region E in addition to the SOA region D. The optical modulation region E acts as an optical modulator for modulating the laser light. In the third embodiment, the optical modulation region E has a Mach-Zehnder optical modulator structure. The optical modulation region E divides a laser light emitted from the SOA region D into two laser lights with two optical waveguides (two arms), modulates a phase relation between the two laser lights, multiplexes the two laser lights, and outputs the multiplexed laser light. A transmission signal is fed into as a modulation signal of the phase relation.

The optical modulation region E is combined to the SOA region D. The optical modulation region E has a structure in which the n-type lower cladding layer 2, a MZ-waveguide portion 22, the p-type upper cladding layer 6, a p-type contact layer 23, and a modulation electrode 24 are laminated in this order on the substrate 1. The MZ-waveguide portion 22 has a structure in which a waveguide region 221 acting as the arms and a modulation region 222 for phase modulation are combined to each other. The waveguide region 221 is, for example, a waveguide layer made of Ga_{0.22}In_{0.78}As_{0.47}P_{0.53}. The modulation region 222 has a structure in which a well layer and a barrier layer having a different composition are laminated alternately. The well layer is, for example, made of Ga_{0.28}In_{0.72}As_{0.85}P_{0.15} having a thickness of 5 nm. The barrier layer is, for example, made of InP having a thickness of 10 nm. The contact layer 23 is, for example, made of p-type Ga_{0.47}In_{0.53}As crystal.

In the embodiment, the SG-DFB region A has a structure in which the active layer 3 and a refractive-index-controllable region 31 are alternately located one or more times. The contact layer 7 is separated into parts according to the position of the active layer 3 and the refractive-index-controllable region 31. An electrode 81 providing electrical current for controlling the refractive index of the refractive-index-controllable region 31 is provided, in addition to the electrode 8 providing the drive current to the active layer.

The refractive-index-controllable region 31 is used when refractive index of each segment in the SG-DFB region A is controlled. In the embodiment, each refractive-index-controllable region 31 is located near an interface of two adjacent segments. Thus, the refractive index of the both segments is controlled with use of one of the refractive-index-controllable regions 31. That is, the number of the refractive-index-controllable region 31 is half or half plus one of that of the segments.

The refractive-index-controllable region 31 is made of a material different from the active layer 3. Therefore, the active layer 3 and the refractive-index-controllable region 31 are optically connected to each other with Butt-joint. Light tends to be scattered at the Butt-joint, because the Butt-joint is a connection between materials having different refractive index. Therefore, the waveguide may be discontinuous. However, the number of the refractive-index-controllable region 31 is small in the embodiment. Therefore, the discontinuity is restrained.

The refractive index of the refractive-index-controllable region 31 is controlled with electrical current provided to the electrode 81. Thus, peak wavelength of the wavelength characteristics of the SG-DFB region A is controlled. In the contact layer 7, the insulating layer 9 is formed between the electrode 8 and the electrode 81. The refractive-index-controllable region 31 is, for example, made of Ga_{0.28}In_{0.72}As_{0.61}P_{0.39}.

In the embodiment, the AR layer 16 is formed on an facet of the optical modulation region E acting as the front facet of the semiconductor laser 102. The facet of the optical absorption region C acting as the rear facet has reflectivity of 10% or more as well as the first embodiment. The reflectivity is obtained when the multi-layer reflection film is formed, the cleavage face is used, potted resin is used, or adhered protective film is used, as well as the first embodiment.

The electrode 14 may be coupled to the potential of the substrate 1 in common in the semiconductor laser 102, as well as the first embodiment. This allows removal of the photo carrier.

A description will be given of an operation of the semiconductor laser 102. When a predetermined driving current is provided to the electrode 8, each heater 10 generates heat at a predetermined temperature. An electrical current is provided to the electrode 81 in order to control the refractive index of the refractive-index-controllable region 31 to be a predetermined value. Thus, the SG-DFB region A and the CSG-DBR region B select a wavelength, and the semiconductor laser 102 oscillates at the wavelength. In the first embodiment, the wavelength characteristics of the SG-DFB region A is controlled with use of the temperature of the temperature control device. However, in the third embodiment, the wavelength characteristics of the SG-DFB region A is controlled with the current provided to the electrode 81.

The SOA region D amplifies the laser light. The optical modulation region E modulates the amplified light. A modulation signal is provided to the electrode 24, and thereby the phase relation between the two arms is modulated. Two lights having transmitted through the two arms are multiplexed. Thus, the optical output is modulated with the phase relation. The modulation principle is well known with respect to the Mach-Zehnder optical modulator.

In the embodiment, the semiconductor laser 102 has high resistivity against the stray light, because the optical absorption region C is provided and the rear facet has the reflectivity of 10% or more.

### Fourth Embodiment

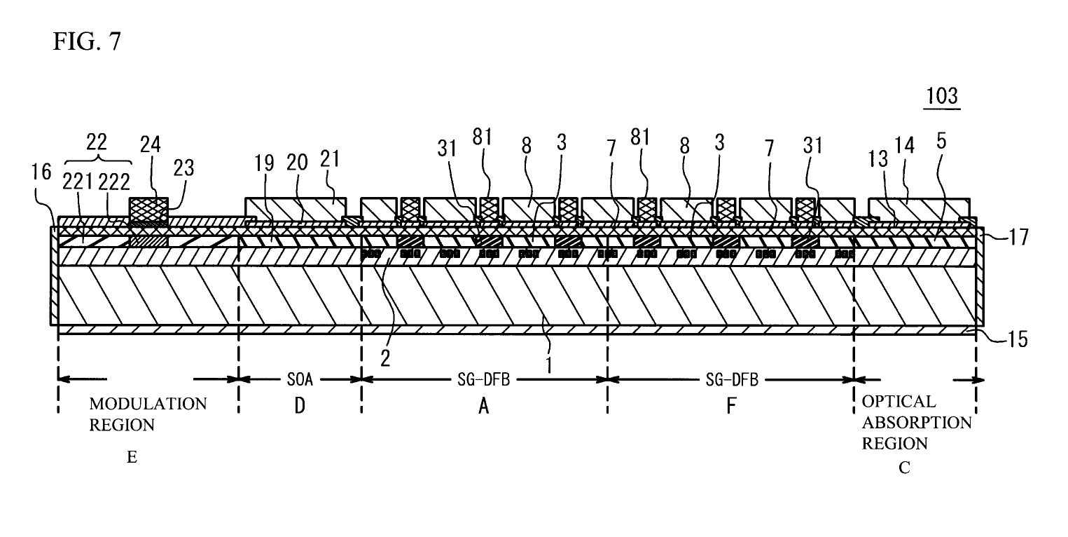

FIG. 7 illustrates a schematic cross sectional view of a semiconductor laser 103 in accordance with a fourth embodiment. The semiconductor laser 103 has a structure in which a SG-DFB region F is provided instead of the CSG-DBR region B in the semiconductor laser 102 of FIG. 6.

The SG-DFB region F has a gain as well as the SG-DFB region A of FIG. 6. The wavelength characteristics of the SG-DFB region F are controllable. The length of the space region of the SG-DFB region F is different from that of the space region of the SG-DFB region A. Therefore, the wavelength characteristics of the SG-DFB region A are different from those of the SG-DFB region F. In the embodiment, a desirable oscillation wavelength is selected with vernier effect with use of the difference of the wavelength characteristics of the SG-DFB region A and the SG-DFB region F. The other structure is the same as the semiconductor laser 102 of FIG. 6.

In the embodiment, the AR layer 16 is formed on an facet of the optical modulation region E acting as the front facet of the semiconductor laser 103. The facet of the optical absorption region C acting as the rear facet has reflectivity of 10% or more. The reflectivity is obtained when the multi-layer reflection film is formed, the cleavage face is used, potted resin is used, or adhered protective film is used, as well as the first embodiment.

The electrode 14 may be coupled to the potential of the substrate 1 in common in the semiconductor laser 103, as well as the first embodiment. This allows removal of the photo carrier. And, the semiconductor laser 103 has high resistivity against the stray light, because the optical absorption region C is provided and the rear facet has the reflectivity of 10% or more.

### Fifth Embodiment

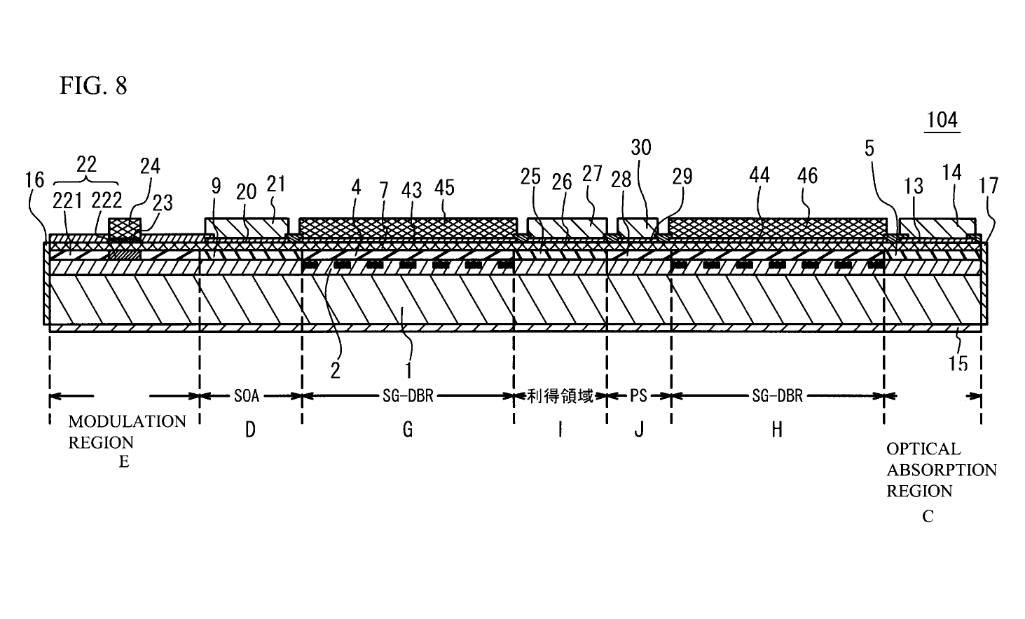

FIG. 8 illustrates a schematic cross sectional view of a semiconductor laser 104 in accordance with a fifth embodiment. As illustrated in FIG. 8, the semiconductor laser 104 has a structure in which two SG-DBR (Sampled Grating Distributed Reflector) regions G and H, a gain region I between the SG-DBR regions G and H and a PS (Phase Shifter) region J are provided instead of the SG-DFB regions A and F in the semiconductor laser 103 of FIG. 7.

The SG-DBR regions G and H have a plurality of segments made of a diffraction grating and a space portion. The space regions of the segments of the SG-DBR region G have the same length. The space regions of the segments of the SG-DBR region H have the same length. However, the length of the space regions of the SG-DBR region G is different from that of the space regions of the SG-DBR region H. Therefore, wavelength characteristics of the SG-DBR region G are different from those of the SG-DBR region H. The wavelength characteristics of the SG-DBR regions G and H are controlled when the electrical current is provided to the SG-DBR regions G and H. And so, contact layers 43 and 44 and electrodes 45 and 46 are provided in the SG-DBR regions G and H.

The gain region I has a structure in which the lower cladding layer 2, a gain layer 25, the upper cladding layer 6, a contact layer 26 and an electrode 27 are laminated on the substrate 1. The gain layer 25 has a structure in which a well layer and a barrier layer having a different material are laminated in order. The well layer is, for example, made of Ga_{0.32}In_{0.68}As_{0.92}P_{0.08} having a thickness of 5 nm. The barrier layer is, for example, made of Ga_{0.22}In_{0.78}As_{0.47}P_{0.53} having a thickness of 10 nm. The contact layer 26 is, for example, made of InGaAsP crystal.

The PS region J has a structure in which the lower cladding layer 2, a waveguide core 28, the upper cladding layer 6, a contact layer 29 and an electrode 30 are laminated in this order on the substrate 1. The waveguide core 28 is, for example, made of bulk material, and may be a waveguide layer made of Ga_{0.28}In_{0.72}As_{0.61}P_{0.39}. The contact layer 29 is, for example, made of InGaAsP crystal.

In the embodiment, electrical current is provided to the electrode 27. Refractive index of the SG-DFB regions G and H is controlled to be a predetermined value when electrical current is provided into the SG-DFB regions G and H. The PS region J controls a phase of a light when electrical current is provided into the PS region J. Thus, the semiconductor laser 104 oscillates at a wavelength determined by the characteristics of the SG-DBR regions G and H and the PS region J. The SOA region D amplifies the laser light. The optical modulation region E modulates the laser light. The modulated laser light is output from the frond facet.

In the embodiment, the AR layer 16 is the front facet of the semiconductor laser 104, and is formed on the facet of the optical modulation region E. The facet of the optical absorption region C acting as the rear facet has reflectivity of 10% or more as well as the first embodiment. The reflectivity is obtained when the multi-layer reflection film is formed, the cleavage face is used, potted resin is used, or adhered protective film is used, as well as the first embodiment.

The electrode 14 may be coupled to the potential of the substrate 1 in common in the semiconductor laser 104, as well as the first embodiment. This allows removal of the photo carrier. And, the semiconductor laser 104 has high resistivity against the stray light, because the optical absorption region C is provided and the rear facet has the reflectivity of 10% or more.

The present invention is not limited to the specifically disclosed embodiments and variations but may include other embodiments and variations without departing from the scope of the present invention.

What is claimed is:

1. A wavelength tunable semiconductor laser comprising:
a first facet having reflectivity of 10% or more;
a second facet;
a wavelength selection portion between the first facet and the second facet; and
an optical absorption region between the first facet and the wavelength selection portion.

2. The wavelength tunable semiconductor laser as claimed in claim 1, wherein:
the optical absorption region is between a p-type semiconductor layer and an n-type semiconductor layer; and
a conductor electrically couples the p-type semiconductor layer and the n-type semiconductor layer.

3. The wavelength tunable semiconductor laser as claimed in claim 1, wherein the wavelength selection portion has one of structures,
the structures being a combination of a SG-DFB and a CSG-DBR, a combination of two SG-DFBs, or a combination of two SG-DBRs and a phase shift region between the two SG-DBRs,
the SG-DFB having a plurality of segments including a space region between diffraction gratings and having a gain,
the CSG-DBR having a plurality of segments including a space region between diffraction gratings, each space region having a different length,
the SG-DBR having a plurality of segments including a space region between diffraction gratings.

4. The wavelength tunable semiconductor laser as claimed in claim 1, wherein output optical intensity from the first facet is 1/100 or less of output optical intensity from the second facet.

5. The wavelength tunable semiconductor laser as claimed in claim 1, wherein the reflectivity of the first facet is 20% or more.

6. The wavelength tunable semiconductor laser as claimed in claim 1, wherein a dielectric multi-layer film is formed on the first facet, the dielectric multi-layer film having one or more combination of a first dielectric material having a thickness corresponding to an optical length of ¼ of an oscillation wavelength of the wavelength tunable semiconductor laser and a second dielectric material having a thickness corresponding to the optical length of ¼ of the oscillation wavelength of the wavelength tunable semiconductor laser and having refractive index less than that of the first dielectric material.

7. The wavelength tunable semiconductor laser as claimed in claim 1, wherein the first facet is a cleavage face.

8. The wavelength tunable semiconductor laser as claimed in claim 7, wherein a resin is adhered to the cleavage face.

9. The wavelength tunable semiconductor laser as claimed in claim 7, wherein a dielectric material having a thickness corresponding to an optical length of 1/10 or less of an oscillation wavelength of the wavelength tunable semiconductor laser is adhered to the cleavage face.

10. The wavelength tunable semiconductor laser as claimed in claim 1, wherein the optical absorption region is made of a material having absorption edge wavelength longer than an oscillation wavelength of the wavelength tunable semiconductor laser.

11. The wavelength tunable semiconductor laser as claimed in claim 1, wherein the optical absorption region is made of the same material as an active layer for giving a gain to the wavelength tunable semiconductor laser.

12. The wavelength tunable semiconductor laser as claimed in claim 1, wherein the reflectivity of the second facet is 1.0% or less.

13. A wavelength tunable semiconductor laser comprising:
a first facet having reflectivity of 10% or more to inside of the semiconductor laser;
a second facet for output;
a wavelength selection portion having diffraction gratings and positioned between the first and the second facet;
an optical absorption region located between the first facet and the wavelength selection portion.

14. The wavelength tunable semiconductor laser as claimed in claim 13,
wherein:
the wavelength selection portion has a SG-DFB section and a CSG-DBR section;
the SG-DFB section has a plurality of segments with a gain, the segments having a space region located between diffraction gratings; and
the CSG-DBR section has a plurality of segments, the segments having a space region located between diffraction gratings, at least two segments having the space region of different length.

15. The wavelength tunable semiconductor laser as claimed in claim 14, wherein:
the SG-DFB section has active regions and refractive index-controllable regions; and
the active regions and refractive index-controllable regions are positioned alternately.

16. The wavelength tunable semiconductor laser as claimed in claim 13, wherein output optical intensity from the first facet is 1/100 or less of output optical intensity from the second facet.

17. The wavelength tunable semiconductor laser as claimed in claim 13, wherein refractivity of the first facet to inside of the semiconductor laser is 20% or more.

18. The wavelength tunable semiconductor laser as claimed in claim 13, wherein refractivity of the second facet to inside of the semiconductor laser is 10% or less.
